(19) United States
(12) Patent Application Publication
(10) Pub. No.: US 2012/0107487 A1
(43) Pub. Date: May 3, 2012

(54) ROLL TO ROLL PATTERNED DEPOSITION PROCESS AND SYSTEM

(75) Inventors: Vincent Cannella, Beverly Hills, MI (US); Raymond Crucet, Ferndale, MI (US)

(73) Assignee: United Solar Ovonic LLC, Auburn Hills, MI (US)

(21) Appl. No.: 12/912,844

(22) Filed: Oct. 27, 2010

(51) Int. Cl. C23C 16/04; B05D 5/06; B05C 13/00

(52) U.S. Cl. 427/66; 118/500; 118/33; 118/718

(57) ABSTRACT

A continuous roll-to-roll apparatus for providing a patterned deposit of a material onto a moving substrate web includes a payout station for feeding out a substrate web, a take-up station for taking up the substrate web, and a web transport system for advancing the web through the apparatus from the payout station to the take-up station. The apparatus includes at least one deposition station disposed between the payout station and the take-up station, and the deposition station is operative to deposit a material onto the web as it moves therethrough. The apparatus includes a masking system associated with a deposition station. The masking system is operative to dispose a deposition mask in registry with a portion of the length of the moving web. The deposition mask is comprised of a plurality of filaments which are aligned with the longitudinal axis of the web. The filaments are spaced from one another in a direction transverse to the longitudinal axis, and the masking system is further operative to move the filaments along the longitudinal axis, and the filaments function to selectively mask longitudinal portions of the moving web so as to prevent the deposition of material thereupon. Also disclosed are methods for utilizing the system.

### FIELD OF THE INVENTION

This invention relates to roll-to-roll deposition processes and systems and more specifically to roll-to-roll deposition processes in which a patterned deposit of a material is formed onto a continuously moving substrate. In specific instances, the invention is directed to patterned deposition processes as used for the fabrication of organic light emitting diodes.

### BACKGROUND OF THE INVENTION

Roll-to-roll vacuum deposition processes can be employed to deposit thin film layers of metals, semiconductors, optical coatings, and the like under accurate control and at relatively high rates of speed. Consequently, such processes are widely used in the fabrication of semiconductor devices, optical devices, and the like. In many instances, the fabrication of particular devices requires that various of the thin film layers constituting the device be patterned to define electrodes or other such elements. In some instances, such patterning is carried out in a post-deposition process by the utilization of techniques such as laser scribing, water jet scribing, or chemical etching. Such offline processes tend to be slow; furthermore, they require removal of the process material from the roll-to-roll vacuum deposition system thereby complicating the fabrication of devices which require subsequent layers to be deposited atop the patterned layer.

In view of the foregoing, the art has looked to implement roll-to-roll deposition processes which are capable of producing patterned deposits and which thereby eliminate the need for offline patterning steps. One such approach involves what is referred to as a “step-and-repeat” patterning process in which the motion of a portion of a moving substrate web is halted in a deposition station, while that substrate portion is contacted with a static deposition mask. A layer of material is then deposited onto the masked substrate so as to produce a patterned structure. The mask is then removed from the substrate and the coated portion is advanced while a new portion is moved into the deposition station and the process repeated. This step-and-repeat type of process requires that the apparatus include a first vacuum accumulator chamber upstream of the processing station and a second vacuum accumulation chamber downstream of the processing station. These chambers accumulate and pay out lengths of the moving substrate web while the deposition is taking place on the halted portion. Such systems are relatively complex and large, and relatively slow in operation. Consequently, it is desirable to have a patterned deposition process which operates “on the fly” without requiring halting of the web. One such on-the-fly system is shown in U.S. Pat. No. 5,717,563 which discloses a process for patterning capacitor electrodes. In this process, two separate deposition masks are utilized in conjunction to produce a graded deposit of electrode material onto a moving web. A first mask is static and defines a basic pattern of the deposit, while a second mask moves in a reciprocal path of travel transverse to web travel so as to gradate the deposit defined by the first mask. The system is capable of producing large scale gradual variations in the deposited material; however, it cannot be adapted to produce finely patterned deposits as may be required in many types of electronic devices.

Organic light emitting diodes (OLEDs) are in increasing use as energy-efficient alternatives to fluorescent lighting. OLEDs are made by depositing organic layers onto a transparent anode and then applying a metallic cathode layer thereatop. High volume production of large area OLEDs is advantageously accomplished utilizing roll-to-roll technology. In a typical process, a substrate material is coated with a transparent anode material, and a number of organic layers are deposited thereupon, typically by a solution deposition process. In a final step of the construction of the OLEDs, a body of cathode material is deposited atop the organic layer. This deposition is advantageously carried out in a roll-to-roll vacuum evaporation process. The cathode of the OLED device must be appropriately patterned, and presently the rate limiting process in the fabrication of OLED devices is the patterning of the cathode. The standard cathode preparation process involves the deposition of a cathode activation layer atop the organic body, followed by a two step metal evaporation process. An initial slow evaporation process is used to provide a protective layer at the junction with the activation layer, then a second higher rate deposition is used to achieve the desired cathode thickness. Each of these layers must be appropriately patterned; furthermore, patterning must be kept in strict alignment if a functioning device is to be produced. Finally, any such process must also be implemented in a manner which will avoid overheating of the substrate web and organic layers. As noted above, step-and-repeat processes are slow and complicated and furthermore present specific problems with regard to mask alignment. Therefore, it will be appreciated that with regard to OLEDs in particular, as well as roll-to-roll deposition processes in general, there is a need for a patterning process which can be carried out continuously, in a roll-to-roll manner, and which allows for the alignment of a mask pattern throughout a series of deposition steps. As will be explained hereinbelow, the present invention provides for a deposition process which meets these requirements. These and other advantages of the invention will be apparent from the drawings, discussion, and description which follow.

### BRIEF DESCRIPTION OF THE INVENTION

Disclosed is a continuous roll-to-roll apparatus for providing a patterned deposit of a material onto a moving substrate web. The apparatus comprises a payout station for feeding out a substrate web, a take-up station for taking up the substrate web, and a web transport system for advancing the web through the apparatus from the payout station to the take-up station. The apparatus further includes a deposition station disposed between the payout station and the take-up station so that the web passes therethrough. The deposition station is operative to deposit a material onto the moving web. The apparatus further includes a masking system associated with the deposition station. The masking system is operative to dispose a deposition mask in registry with a portion of the length of the moving web. The deposition mask is comprised of a plurality of filaments which are aligned with a longitudinal axis of the web. The filaments are spaced from one another in a direction which is transverse to the longitudinal axis, and the masking system is further operative to move the filaments along the longitudinal axis so that the filaments selectively mask longitudinal portions of the moving web so as to prevent the deposition of material thereupon.

In specific embodiments, the masking system includes a feed-out roller having a length of each of the filaments wound thereabout in a spaced apart relationship and a take-up roller having a length of each of the plurality of filaments wound thereabout in a spaced apart relationship. The rolls are operative in combination to move the filaments along the longitudinal axis. Motion of the filaments may be in the same direction as the motion of the substrate web or the motion may be opposite the direction of the motion of the substrate web. The masking system may further include a tensioner for maintaining tension in the filaments. The deposition station may include a support body which engages and supports the back surface of the web while material is being deposited onto the front surface. The support body may be configured as a roller and may be optionally cooled.

In some specific embodiments, the apparatus includes a plurality of deposition stations and a corresponding plurality of masking systems. And, such multi station systems may also include one or more alignment devices for assuring that the patterned deposits produced in each of the stations are appropriately aligned with one another.

Further disclosed are methods for depositing pattern layers through the use of the apparatus of the present invention, and specifically disclosed is a method for preparing a patterned cathode structure for an organic light emitting diode.

### BRIEF DESCRIPTION OF THE DRAWINGS

FIG. 1 is a schematic depiction of a three station deposition apparatus structured in accord with the principles of the present invention;

FIG. 2 is a detail of the support roller, web transport system, and masking system of one of the chambers of FIG. 1;

FIG. 3 is an enlarged detail of the FIG. 2 drawing showing details of the masking system;

FIG. 4 is a top plan view of a portion of a substrate web comprising an OLED having a patterned cathode body thereatop; and

FIG. 5 is a cross-sectional view of the web of FIG. 4 taken along line V-V.

### DETAILED DESCRIPTION OF THE INVENTION

The present invention may be configured in a variety of embodiments and will be explained herein with regard to some specific embodiments, and it is to be understood that yet other embodiments may be implemented in accord with the teaching herein. In general, the present invention comprises a roll-to-roll apparatus for providing a patterned deposit of a material onto a moving web of substrate material. In that regard, the system includes a deposition station which may be a vacuum evaporation station, a plasma deposition station, a sputtering station, or the like. The deposition station is disposed and operative to deposit a layer of material onto a substrate web moving there past. The apparatus of the present invention includes a masking system associated with the deposition station. The masking system is operative to dispose a deposition mask in registry with a portion of the length of the moving web. The deposition mask comprises a plurality of filaments which are aligned with the longitudinal axis of the web such that the filaments are spaced from one another in a direction transverse to the longitudinal axis. The masking system is further operative to move the filaments along the longitudinal axis so that they selectively mask longitudinal portions of the moving web so as to prevent the deposition of the material thereupon.

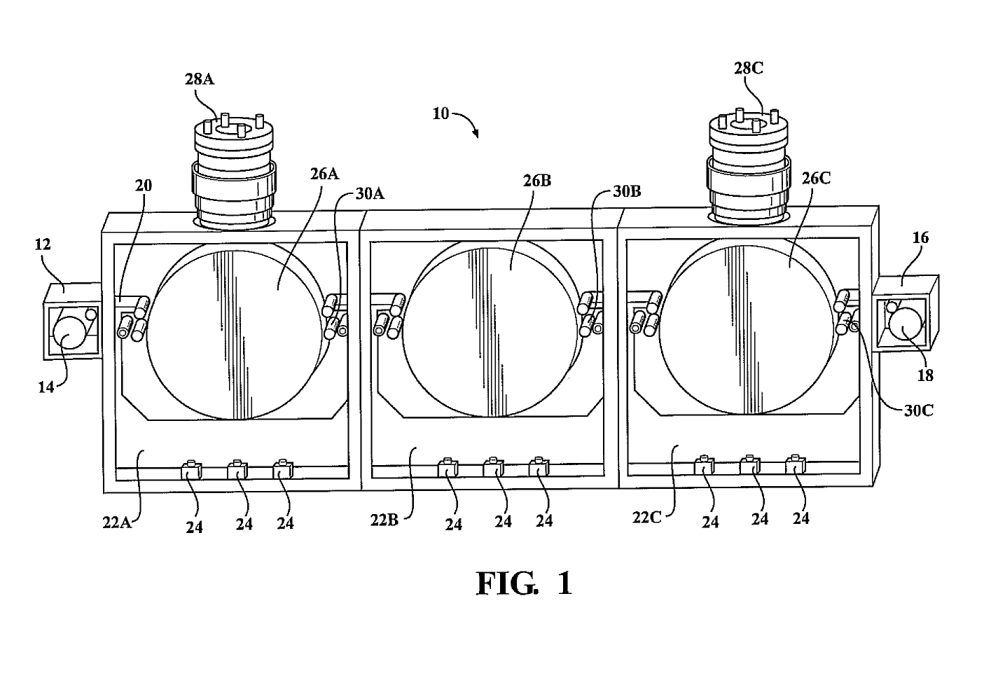

Referring now to FIG. 1, there is shown a deposition apparatus 10. The apparatus 10 of FIG. 1 includes a payout station 12 which contains a payout roller 14 having a substrate material wound thereabout. The apparatus 10 further includes a take-up station 16 having a substrate take-up roller 18 disposed therein. The payout and take-up stations cooperate to advance a web of substrate material 20 through the remainder of the apparatus.

The apparatus of FIG. 1 includes three separate deposition stations 22a, 22b and 22c disposed in series. It is to be understood that other systems may include a larger number or a smaller number of deposition stations, and in some instances the apparatus will include one deposition station. In the FIG. 1 embodiment, each deposition station is configured and operative to vacuum deposit a material onto the substrate 20 as it passes therethrough. In this regard, each station includes three separate vacuum evaporation sources 24 therein, and it is to be understood that other embodiments may include larger or smaller numbers of evaporation sources. Also, the present invention may be implemented utilizing other deposition sources such as plasma chemical vapor deposition sources, sputtering sources, and the like.

Each of the deposition stations 22 includes a roller 26a, 26b, 26c disposed so as to engage and support a portion of the length of the substrate 20 as it advances through the respective deposition station. As will be explained in detail hereinbelow, the rollers 26 stabilize the substrate during the deposition process and also facilitate positioning and alignment of the deposition mask. In addition, the rollers 26 provide heat sinking for the substrate 20 thereby preventing overheating of the substrate and deposited layers. This heat sinking may be further facilitated by cooling the rollers 26, as for example by flowing a coolant fluid or gas therethrough.

In the illustrated system, the deposition chambers 26, payout station 12, and take-up station 16 are all in communication with one another via gas gates which permit passage of the substrate therethrough. There are a variety of such gates known and available to those of skill in the art, and the present invention may be implemented utilizing such available structures. In the FIG. 1 embodiment, vacuum pumps 28a and 28c are associated with deposition stations 22a and 22c respectively. Given that the stations are in communication, either of these pumps 28 will also provide a low-pressure environment in chamber 22b. In other embodiments, each chamber may have its own vacuum pump associated therewith, or a single pump may service the entirety of the apparatus.

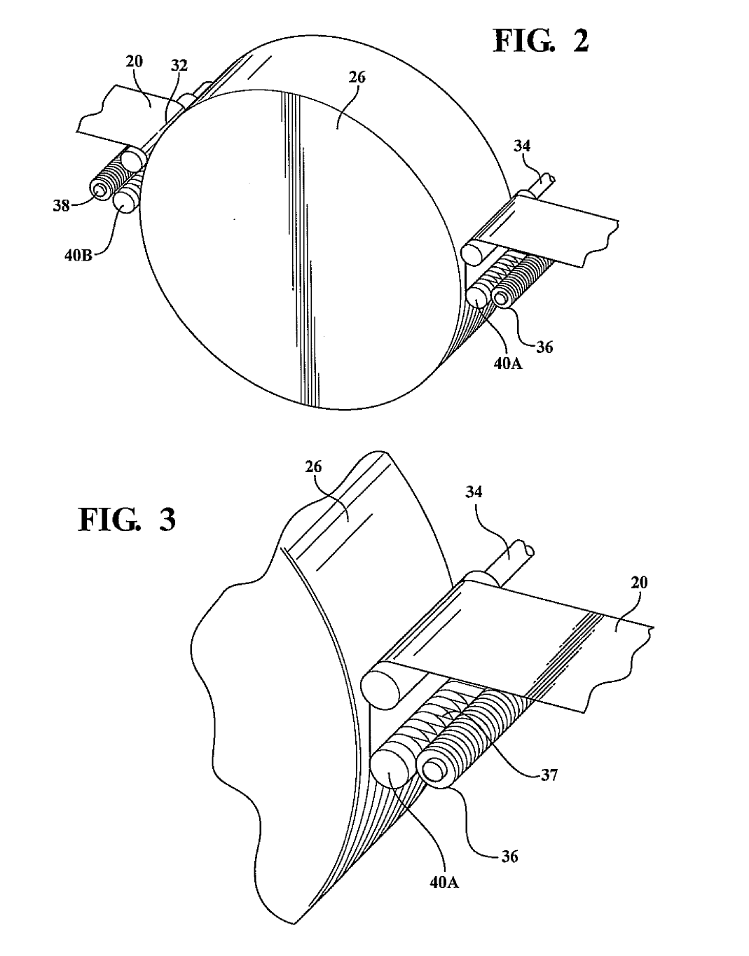

Each of the deposition stations has a masking system 30 associated therewith, and the masking system is shown in better detail in FIGS. 2 and 3.

FIG. 2 is a perspective view of a portion of a deposition station of FIG. 1 illustrating a support roller 26 together with associated components of the web transport system and masking system. As will be seen in FIG. 2, a substrate web 20 is directed by a pair of substrate guide rollers 32 and 34 which serve to wrap a portion of the length of the substrate 20 about the support drum 26. As further shown in FIG. 2, the masking system is disposed and operative so as to direct a plurality of filaments into registry with the substrate 20 which is wrapped about the drum 26. The masking system includes a feed-out roller 36 which has a plurality of filaments wound thereabout in a spaced apart relationship. The feed-out roller 36 cooperates with a take-up roller 38 so as to advance the plurality of filaments in a spaced apart relationship along the lengthwise dimension of the substrate. It should be noted that the direction of travel of the filaments may be in the direction of travel of the substrate web or it may be counter to the direction of web travel; and, as will be detailed below, moving the filaments counter to the direction of web travel aids, in some instances, in maintaining filament/substrate alignment.

The masking system further includes a first slotted alignment roller 40a associated with the payout roller 36 and a second slotted alignment roller 40b associated with the take-up roller 38. The slots in the rollers function to guide the filaments in a precise path of travel relative to the substrate; and these grooves may be square-sided, V-shaped, curve-sided, or otherwise configured. It will be appreciated that tracking of the filaments may be readily controlled by controlling the motion of the alignment rollers 40. Such control may be achieved by use of solenoids or other actuators operating in combination with a tracking device such as an optical tracking device so as to establish a feedback loop assuring proper positioning of the filaments.

Referring now to FIG. 3, there is shown an enlarged detail of a portion of the FIG. 2 illustration specifically showing the support drum 26, substrate guide roller 34, and associated substrate. Further shown in FIG. 3 is the payout roller 36 and alignment roller 40a. As will be seen in FIG. 3, the payout roller 36 includes a plurality of filaments, such as representative filament 37. In a typical implementation, the plurality of filaments wound about the payout roller will be at least three in number, and in some specific instances at least five filaments will be wound thereabout. The filaments may comprise metallic wires or polymeric bodies. The filaments may have a circular cross section as well as an oval or flattened cross section. The transverse dimension of the filament will depend upon the masked features to be produced; however, typically the filaments will have a transverse dimension in the range of 0.1-0.005 inch. In one specific embodiment configured to pattern OLED cathodes, the filaments will comprise wires which have a diameter of approximately 0.010 inch±0.001 inch. As noted above, the alignment roller 40a includes grooves, which are preferably V-shaped grooves, which guide and direct the filaments into registry with the substrate 20. In particular instances, the filaments will be maintained in direct contact with the substrate, although in other implementations of the invention they may be maintained in a spaced apart relationship. The filaments may be provided in the form of a pre-wound cartridge, and in some specific instances, the used filaments may be cleaned and recycled for subsequent use, while in other instances they may be discarded after one use.

The masking system may include biasing springs (not shown) associated with the payout and take-up rollers 36 which serve to maintain the filaments in a taut state so as to maintain their alignment relative to the substrate 20. The payout and take-up rollers 36 and 38 may include one or more drive motors associated therewith for actively transporting the filaments.

An apparatus generally similar to that shown in FIG. 1 may be employed to prepare cathode structures for OLEDs. In such instance, a body of substrate material which typically comprises a transparent polymeric material is first coated with a transparent electrically conductive anode material such as a transparent conductive metal oxide. Such coating may be accomplished by sputtering techniques, evaporation techniques, or solution deposition; and the anode material may be appropriately patterned. Subsequently, the organic component of the OLED, typically in the form of two separate layers, is coated atop the anode. This coating step is generally accomplished by a solution deposition process. The substrate having the anode and organic component is then loaded into the payout chamber 12 of the FIG. 1 system and subsequently conveyed through the three deposition chambers 22a, 22b, 22c. In the first chamber 22a, an activation layer is vacuum evaporated and deposited onto the uppermost surface of the active body of organic material. The substrate is then advanced through the second deposition station 22a in which a layer of metal, typically aluminum, is evaporated onto the activation layer at a relatively slow deposition rate. This is done so as to prevent damage to the activation layer and underlying organic layer. The substrate is then advanced through deposition station 22c, and a relatively thick layer of metal (again typically aluminum) is evaporated thereonto. The thus coated substrate is wound onto the take-up roll 18 in the take-up chamber 16. Other implementations of this process are also possible within the scope of this invention. For example, the substrate web having the organic material deposited thereupon may be directly fed into the deposition apparatus through an air-to-vacuum (ATV) module. Yet other modifications are possible.

In the foregoing process, masking systems 30a-30c cooperate so as to maintain registry of the masking filaments with regard to the three stations so that each of the three depositions are aligned. Deposition of the activating material in the first station 22a will produce a pattern on the substrate web, and this pattern can be used by the masking system 30b in the second deposition station 22b to align the filaments of the second masking system 30b with the previously deposited pattern. This can be accomplished, for example, by the use of an optical scanning system which views the pattern on the web and correspondingly adjusts the alignment rollers 40a, 40b of the second masking system 30b. Similarly, deposition of the third layer may be controlled with regard to the third masking system 30c. In this manner, three independently functioning, but mutually controlled, masking systems will cooperate to maintain precise alignment of the deposited patterns on the web.

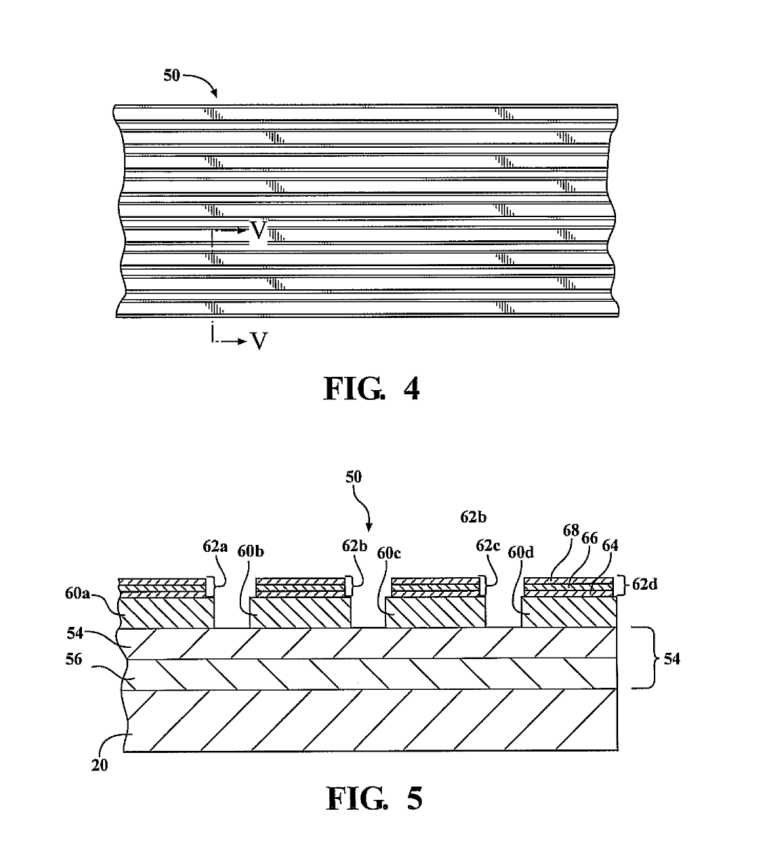

Referring now to FIG. 4, there is shown a top plan view of a portion of a large area OLED device 50 of the type which may be prepared in the system of FIG. 1. FIG. 5 is a cross-sectional view of the device 50 taken along line V-V. The device 50 includes a substrate 20 which comprises a transparent polymer material. A pair of interconnect layers 52, 54 are disposed atop the substrate 20. These layers 52, 54 form the anode portion of the OLED; and as is known in the art, such layers may be comprised of a transparent electrically conductive material such as a transparent electrically conductive oxide. Disposed atop the interconnect layers is a patterned body of the organic light emitting diode material. As will be seen in FIG. 5, this OLED material is divided into a plurality of discrete bodies 60a-60d. There are a variety of OLED materials which may be utilized, as is known in the art, and such materials may comprise a single layered structure or a dual layered structure. The combination of the substrate 20, interconnect layers 52 and 54, and OLED material 60 may be prepared in accord with conventional deposition and patterning procedures as discussed above, and it is this combination of layers which is coated with a patterned deposit in accord with the present invention.

As will be further seen in FIG. 5, each of the bodies of OLED material 60a-60d has a cathode structure 62a-62d deposited thereatop. The cathode structure 62 is in turn comprised of three separate layers prepared according to the pattern deposition process of the present invention. These layers will be described with reference to cathode structure 62d, it being understood that the remaining cathode structures are identical. As will be seen in FIG. 5, the cathode structure 62d includes a first layer 64 which is disposed atop the OLED material 60d. This layer 64 is an activating layer, and as is known in the art, there are a variety of materials, such as calcium or other active materials, which can function as activating layers for OLED devices. Disposed atop the activating layer 64 is a first, relatively thin metal layer 66 typically comprised of aluminum. This layer is deposited at a relatively low rate so as to avoid disrupting the activation layer 64, and in particular the interface of this activation layer 64 with the OLED body 60d. Disposed atop the first metal layer 66 is a second, relatively thicker layer of metal, typically deposited at a higher rate of speed, and also typically formed of aluminum. Use of the deposition system of the present invention allows the three layers 64, 66 and 68 to be deposited in precise registry with both one another and with the body of OLED material 60d.

As will be appreciated, the present invention provides a method and apparatus by which precisely defined pattern structures may be formed in connection with the vapor deposition of a variety of materials. The present invention employs a masking system which operates to move a mask comprised of a plurality of filaments along the length of a substrate web which is advancing through the deposition station. The alignment of the mask may be very precisely controlled so as to allow for the coordinated deposition of succeeding bodies of materials.

In view of the foregoing, other modifications and variations of this system will be apparent to those of skill in the art. The foregoing drawings, discussions, and examples are illustrative of specific embodiments of the invention but are not meant to be limitations upon the practice thereof. It is the following claims, including all equivalents, which define the scope of the invention.

1. A continuous, roll-to-roll apparatus for providing a patterned deposit of a material onto a moving substrate web, said apparatus comprising:
a payout station for feeding out a substrate web;
a take-up station for taking up said substrate web;
a web transport system for advancing said web through said apparatus from said payout station to said take-up station;
a deposition station disposed between said payout station and said take-up station so that said web passes therethrough, said deposition station being operative to deposit a material onto said moving web; and
a masking system associated with said deposition station, said masking system being operative to dispose a deposition mask in registry with a portion of the length of said moving web, said deposition mask comprising a plurality of filaments which are aligned with a longitudinal axis of said web, said filaments being spaced from one another in a direction transverse to said longitudinal axis, said masking system being further operative to move said filaments along said longitudinal axis so that said filaments selectively mask longitudinal portions of said moving web so as to prevent the deposition of said material thereupon;
whereby said apparatus is operative to produce a patterned deposit of said material on said moving web.

2. The apparatus of claim 1, wherein said masking system includes a feed-out roller having a length of each of said plurality of filaments wound thereabout in a spaced apart relationship and a take-up roller having a length of each of said plurality of filaments wound thereabout in a spaced apart relationship, said rolls being operative in combination to move said filaments along said longitudinal axis.

3. The apparatus of claim 1, wherein said masking system is further operative to maintain said filaments under tension while they are moving along said longitudinal axis.

4. The apparatus of claim 1, wherein said masking system is further operative to move said filaments along said longitudinal axis in a direction which corresponds to the direction of travel of said web.

5. The apparatus of claim 1, wherein said masking system is operative to move said filaments along said longitudinal axis in a direction which is opposite the direction of travel of said web.

6. The apparatus of claim 1, wherein said masking system is operative to maintain said plurality of filaments in direct contact with said web during at least a portion of the time said web is in said deposition station.

7. The apparatus of claim 1, wherein said deposition station is an evaporation station which is operative to produce a vapor of said material and to deposit said vapor onto said substrate.

8. The apparatus of claim 1, wherein said deposition station is operative to deposit a metal onto said substrate.

9. The apparatus of claim 1, wherein said deposition station further includes a support body which engages and supports a back surface of a portion of said web while said material is being deposited onto a front surface of said portion of said web.

10. The apparatus of claim 9, wherein said support body is chilled to a temperature below the ambient temperature of said deposition station.

11. The apparatus of claim 9, wherein said support body comprises a roller.

12. The apparatus of claim 1, including a plurality of said deposition stations disposed between said payout station and said take-up station, each deposition station having one of said masking systems associated therewith.

13. The apparatus of claim 12, wherein said plurality of deposition stations comprises three deposition stations.

14. The apparatus of claim 12, wherein the masking system of at least one of said deposition stations is operative to align the filaments thereof with a pattern on said web.

15. A continuous method for forming a patterned deposit of a material onto a moving substrate web, said method comprising:
I. providing a deposition apparatus comprising:
a payout station for feeding out a substrate web;
a take-up station for taking up said substrate web;
a web transport system for advancing said web through said apparatus from said payout station to said take-up station;
a deposition station disposed between said payout station and said take-up station so that said web passes therethrough, said deposition station being operative to deposit a material onto said moving web; and
a masking system associated with said deposition station, said masking system being operative to dispose a deposition mask in registry with a portion of the length of said moving web, said deposition mask comprising a plurality of filaments which are aligned with a longitudinal axis of said web, said filaments being spaced from one another in a direction transverse to said longitudinal axis, said masking system being further operative to move said filaments along said longitudinal axis so that said filaments selectively mask longitudinal portions of said moving web so as to prevent the deposition of said material thereupon;
II. providing a web of substrate material;
III. continuously advancing said web of substrate material through said apparatus;
IV. depositing said material onto said web in said deposition station; and
V. operating said masking system so as to dispose said plurality of filaments in registry with a portion of said moving web and move said plurality of filaments along the longitudinal axis of the web while said material is being deposited thereonto.
